(19) United States
(12) Patent Application Publication
(10) Pub. No.: US 2008/0128888 A1
(43) Pub. Date: Jun. 5, 2008

(54) System-in-package (SiP) and method of manufacturing the same

(75) Inventors: Myeong-soon Park, Seoul (KR); In-young Lee, Yongin-si (KR); Ho-jin Lee, Seoul (KR); Moon-sun Seo, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/895,187

(22) Filed: Aug. 23, 2007

(30) Foreign Application Priority Data
Dec. 5, 2006 (KR) 10-2006-0122586

(51) Int. Cl. H01L 23/488; H01L 21/58

(52) U.S. Cl. 257/691; 438/109; 257/E23.023; 257/E21.505

(57) ABSTRACT

Provided is a system-in-package (SiP) including a main chip and one or more sub chips. In the SiP, a first surface of the main chip is electrically connected with a second surface of the main chip, through a via electrode, the one or more sub chips are assembled on the second surface of the main chip on which a ReDistribution Line (RDL) is formed, and the length of the SiP is substantially equal to the length of the main chip.

### CROSS-REFERENCE TO RELATED PATENT APPLICATION

This application claims priority under 35 U.S.C. §119 to Korean Patent Application No. 10-2006-0122586, filed on Dec. 5, 2006, in the Korean Intellectual Property Office, the disclosure of which is incorporated herein in its entirety by reference.

### BACKGROUND OF THE INVENTION

1. Field of the Invention

The present invention relates to a system-in-package (SiP) and a method of manufacturing the same, and more particularly, to a system-in-package (SiP) whose length is equal to the length of a main chip, and a method of manufacturing the SiP.

2. Description of the Related Art

High-speed/high-density semiconductor chips are continuously required in many applications, and can be purchased in the form of a package. Recently, in order to highly integrate such a semiconductor package, a multi-chip package (MCP) technique, a system-in-package (SiP) technique, etc., have been developed. The MCP technique or the SiP technique is a three-dimensional stacking technique for enhancing integration of a package by including a plurality of chips in a single package, and embodying a single system as a single package.

FIGS. 1A and 1B illustrate examples of prior art MCPs or conventional SiPs.

In FIG. 1A, a substrate SUB, chips CHIP1, CHIP2, and CHIP3, a plurality of bonding wires BW11, BW12, BW2, and BW3, a protective layer ENCAP, and an external terminal TER are shown. The upper part of FIG. 1A shows a plan view of the prior art MCP or the prior art SiP, and the lower part of FIG. 1A shows a cross-sectional view of the prior art MCP or the prior art SiP illustrated in the upper part of FIG. 1A.

In FIG. 1B, a substrate SUB, chips CHIP4, CHIP5, CHIP6, and CHIP7, a plurality of bonding wires BW41, BW42, BW51, and BW52, a protective layer ENCAP, and an external terminal TER are shown. The upper part of FIG. 1B is a plan view of another prior art MCP or another prior art SiP, and the lower part of FIG. 1B is a cross-sectional view of another prior art MCP or another prior art SiP illustrated in the upper part of FIG. 1B.

Before such a MCP or SiP was developed, a single package could include only one chip. As illustrated in FIGS. 1A and 1B, since the MCP or SiP can include a plurality of chips therein, it is possible to further enhance the integration of the package.

Meanwhile, in FIG. 1A, the length PL of the package is longer than the length CL1 of the chip CHIP1. Also, in FIG. 1B, the length PL of the package is longer than the length CL4 of the chip CHIP4 and the length CL5 of the chip CHIP5. That is, the conventional MCP or the conventional SiP is manufactured to be larger than the largest chip among a plurality of chips therein. However, if the length of the package can be reduced to be equal to the length of the largest chip therein, the integration of the MCP or the SiP will be further enhanced.

### SUMMARY OF THE INVENTION

In accordance with various aspects of the present invention, provided is a system-in-package (SiP) whose length is substantially equal to the length of a main chip, and a method of manufacturing the SiP.

According to an aspect of the present invention, there is provided a system-in-package (SiP) comprising a main chip having a first surface electrically connected with a second surface of the main chip through a via electrode, a ReDistribution Line (RDL) is formed on the second surface of the main chip, and one or more sub chips assembled on the second surface of the main chip, wherein the length of the SiP is substantially equal to the length of the main chip.

The main chip can be a chip having the longest length among a plurality of chips included in the SiP.

An internal circuit of the main chip can be formed on the first surface of the main chip.

The SiP can include an external terminal formed on the first surface of the main chip and configured to electrically connect the SiP with an external device.

The external terminal can be a solder ball pad, a bonding pad, or a bumping pad.

The main chip can include a plurality of via electrodes.

The RDL can be formed based on the footprints and placement of the one or more sub chips relative to the main chip, and to provide efficient interconnections between the main chip and the one or more sub chips and between the one or more sub chips.

The SiP can include an insulating layer formed on the second surface of the main chip and configured to insulate the RDL.

The SiP can further comprise a protective layer covering the one or more sub chips assembled on the second surface of the main chip.

The SiP can further comprise an insulating layer formed on the second surface of the main chip and configured to insulate the RDL and a protective layer covering the one or more sub chips assembled on the second surface of the main chip, wherein the RDL, the insulating layer, the one or more sub chips, and the protective layer can be sequentially stacked on the second surface of the main chip.

The SiP can be formed at a wafer level.

According to another aspect of the present invention, there is provided a method for manufacturing a system-in-package (SiP), the method including: providing a main chip and one or more sub chips; forming a via electrode electrically connecting a first surface of the main chip with a second surface of the main chip; forming a ReDistribution Line (RDL) on the second surface of the main chip; and assembling the one or more sub chips on the second surface of the main chip on which the RDL is formed so that the length of the SiP is substantially equal to the length of the main chip. and

The method can further include forming a protective layer covering the one or more sub chips assembled on the second surface of the main chip.

The length of the main chip can be greater than the lengths of the one or more sub chips.

The method can further comprise forming an internal circuit of the main chip on the first surface of the main chip.

The method can further comprise forming a plurality of via electrodes through the main chip.

The method can further comprise forming the RDL based on the footprints and placement of the one or more sub chips relative to the main chip, and to provide efficient interconnections between the main chip and the one or more sub chips and between the one or more sub chips.

The method can further comprise forming an insulating layer insulating the RDL.

The method can further comprise electrically connecting the one or more sub chips with the RDL, using a flip chip bonding method or a wire bonding method.

The method can further comprise forming the protective layer using a screen printing method, a spin coating method, a laminating method, or an injection molding method.

The method further can comprise forming an external terminal electrically connecting the SiP with an external device, on the first surface of the main chip.

The method further can comprise forming a plurality of SiPs simultaneously to have the same structure at a wafer level.

The method can further comprise singularizing the plurality of the SiPs simultaneously formed to have the same structure at a wafer level.

According to another aspect of the present invention, there is provided a method for manufacturing a system-in-package (SiP), the method including: providing a main chip and one or more sub chips; forming an internal circuit on a first surface of the main chip; forming a via electrode to a predetermined depth in the main chip; back-lapping a second surface of the main chip so that the via electrode is exposed; forming a ReDistribution Line (RDL) on the second surface of the back-lapped main chip; forming an insulating layer insulating the RDL; assembling the one or more sub chips on the second surface of the main chip so that the one or more sub chips are electrically connected with the RDL; forming a protective layer covering the one or more sub chips; and forming an external terminal on the first surface of the main chip.

The length of the SiP can be substantially equal to the length of the main chip.

### BRIEF DESCRIPTION OF THE DRAWINGS

The above and other features and advantages of the present invention will become more apparent by describing in detail exemplary embodiments thereof with reference to the attached drawings. The drawing figures depict preferred embodiments by way of example, not by way of limitations. In the figures, like reference numerals refer to the same or similar elements, in which:

FIGS. 1A and 1B illustrate plan views and cross-sectional views of prior art multi-chip packages or prior art system-in-package;

FIGS. 2A and 2B illustrate a plan view and cross-sectional views of an embodiment of a SiP according to aspects of the present invention;

FIGS. 3A and 3B are plan views of an embodiment of a SiP according to another aspect of the present invention; and

FIGS. 4A through 4F are views for explaining an embodiment of a method of manufacturing a SiP, according to an aspect of the present invention.

### DETAILED DESCRIPTION OF THE INVENTION

Hereinafter, aspects of the present invention will be described in detail with reference to the embodiments shown in the appended drawings. The present invention can, however, be embodied in different forms and should not be constructed as limited to the embodiments set forth herein.

It will be understood that, although the terms first, second, etc. may be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Hereinafter, a system-in-package (SiP) can be, as an example, a MCP.

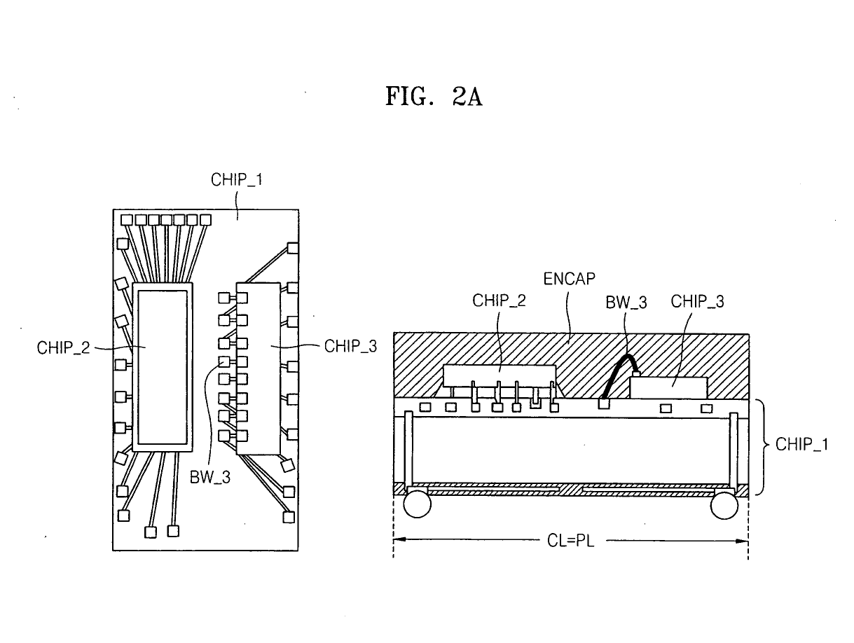

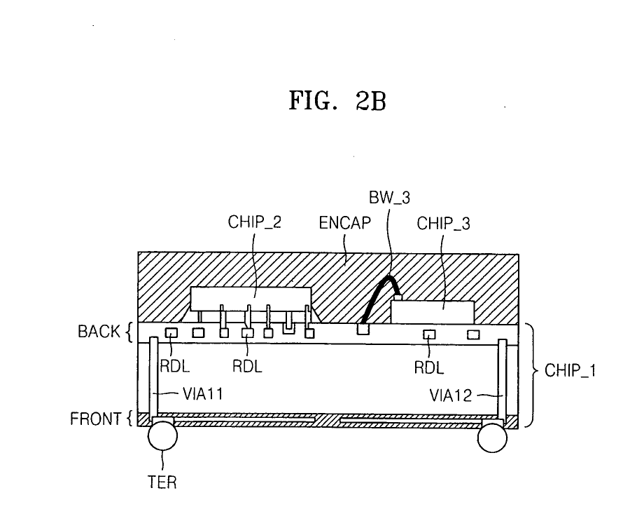

FIGS. 2A and 2B illustrate an embodiment of a SiP according to aspects of the present invention, wherein a first part of FIG. 2A is a plan view of the SiP and a second part of FIG. 2A is a cross-sectional view of the SiP. And FIG. 2B is a detailed view of the second part of FIG. 2A.

In FIGS. 2A and 2B, a main chip CHIP_1, sub chips CHIP_2 and CHIP_3, a bonding wire BW_3 of the sub chip CHIP_3, a protective layer ENCAP, and an external terminal TER are shown.

In the SiP, the main chip CHIP_1 and the sub chips CHIP_2 and CHIP_3 are not classified according to the importance of functions that will be performed by the respective chips.

A chip having the longest length among a plurality of chips included in the SiP is referred to as a “main chip,” and the remaining chips are referred to as sub chips. While in FIGS. 2A and 2B two sub chips CHIP_2 and CHIP_3 are included in a SiP, the present invention is not limited to this embodiment. The present invention can be applied to arbitrary SiPs including one or more sub-chips.

As illustrated in FIGS. 2A and 2B, the main chip CHIP_1 includes two via electrodes VIA11 and VIA12 for electrically connecting a first surface FRONT of the main chip CHIP_1 to a second surface BACK of the main chip CHIP_1, wherein the number of the via electrodes VIA11 and VIA12 can be one or more. FIGS. 2A and 2B illustrate a case where two via electrodes VIA11 and VIA12 are included in the main chip CHIP_1, however, the present invention is not limited to this. The main chip CHIP_1 can include one or more via electrodes. In the specification, the term “front surface FRONT” means a front side, and the term “second surface BACK” means a back side.

A ReDistribution Line (RDL) is formed on the second surface BACK of the main chip CHIP_1. The RDL is formed in consideration of the locations of the sub chips CHIP_2 and CHIP_3, interconnections between the main chip CHIP_1 and the sub chips CHIP_2 and CHIP_3, and interconnections between the sub chips CHIP_2 and CHIP_3. That is, preferably, the RDL is formed based on the footprints and placement of the sub chips relative to the main chip, provides efficient interconnections between the main chip CHIP_1 and the sub chips CHIP_2 and CHIP_3, and interconnections between the sub chips CHIP_2 and CHIP_3. For example, efficient interconnections can be minimal length connections, respecting any other constraints embodied in the layout in the SiP.

The protective layer ENCAP is provided to physically protect the sub chips CHIP_2 and CHIP_3 assembled on the second surface BACK of the main chip CHIP_1.

As illustrated in FIGS. 2A and 2B, the external terminal TER for electrically connecting the SiP with an external device is formed on the first surface FRONT of the main chip CHIP_1. A solder ball pad, a bonding pad, a bumping pad, etc. can be used as the external terminal TER. However, the present invention is not limited to the above-mentioned pads, and the term “external terminal TER” means an arbitrary interconnection pad for electrically connecting the SiP with an external device.

As illustrated in FIG. 2A, the length PL of the SiP according to the present embodiment is substantially equal to the length CL of the main chip CHIP_1. As described above, the main chip CHIP_1 is a chip having the longest length among the plurality of chips included in the SiP. As such, by minimizing the length PL of the SiP, it is possible to enhance the integration of the SiP.

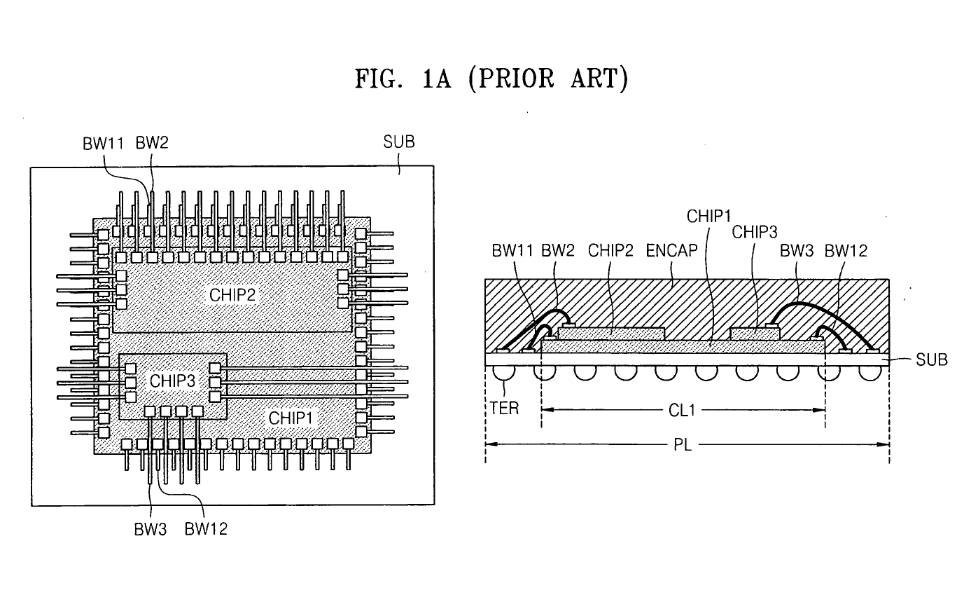

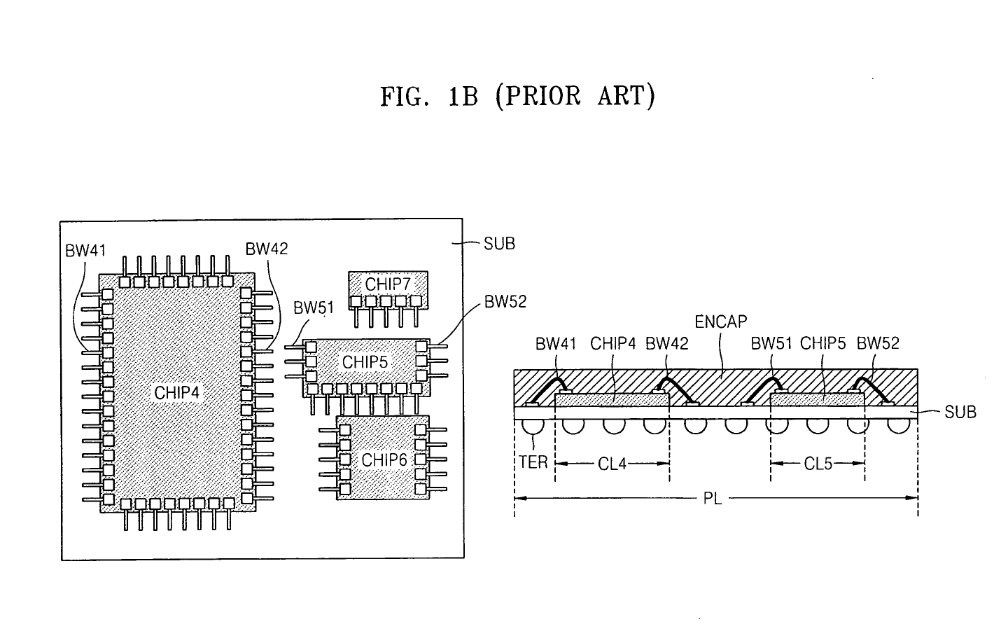

Also, as illustrated in FIGS. 2A and 2B, the SiP does not require any separate substrate SUB, which is different from the case of the conventional SiP illustrated in FIGS. 1A and 1B. This is because the main chip CHIP_1 acts as a substrate. Since the SiP does not require any separate substrate SUB, according to the present embodiment, it is also possible to reduce the thickness of the SiP.

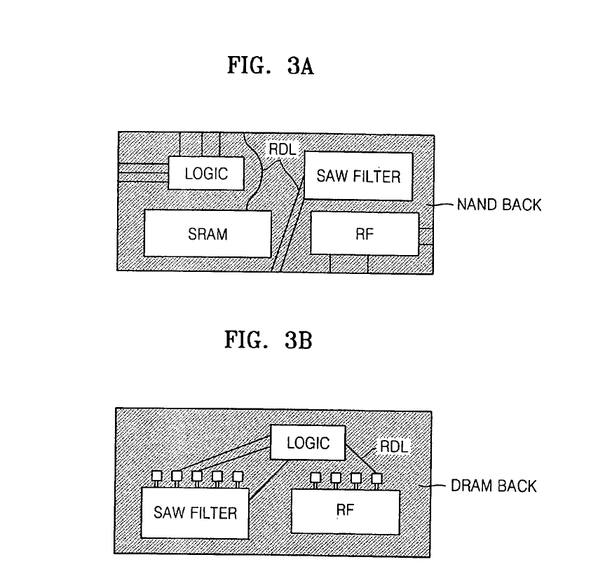

FIGS. 3A and 3B are plan views of another embodiment of a SiP according to another aspect of the present invention. In FIGS. 3A and 3B, parts denoted with shading represent a second surface BACK of a main chip.

In FIG. 3A, a NAND flash memory chip is used as the main chip, and a logic chip LOGIC, a filter chip SAW FILTER, a static random access memory (SRAM) chip, and a high-frequency circuit chip RF correspond to sub chips disposed on the main chip. An RDL is formed on a second surface NAND BACK of the NAND flash memory chip, and the logic chip LOGIC, the filter chip SAW FILTER, the SRAM chip SRAM, and the high-frequency circuit chip RF are assembled on the second surface NAND BACK of the NAND flash memory chip so that they are electrically connected with the RDL.

In FIG. 3B, a dynamic random access memory (DRAM) chip is used as the main chip, and a logic chip LOGIC, a filter chip SAW FILTER, and a high frequency circuit chip RF correspond to sub chips disposed on the main chip. Likewise, an RDL is formed on a second surface DRAM BACK of the DRAM chip, and the logic chip LOGIC, the filter chip SAW FILTER, and the high frequency circuit chip RF are assembled on the second surface DRAM BACK of the DRAM chip so that they are electrically connected with the RDL.

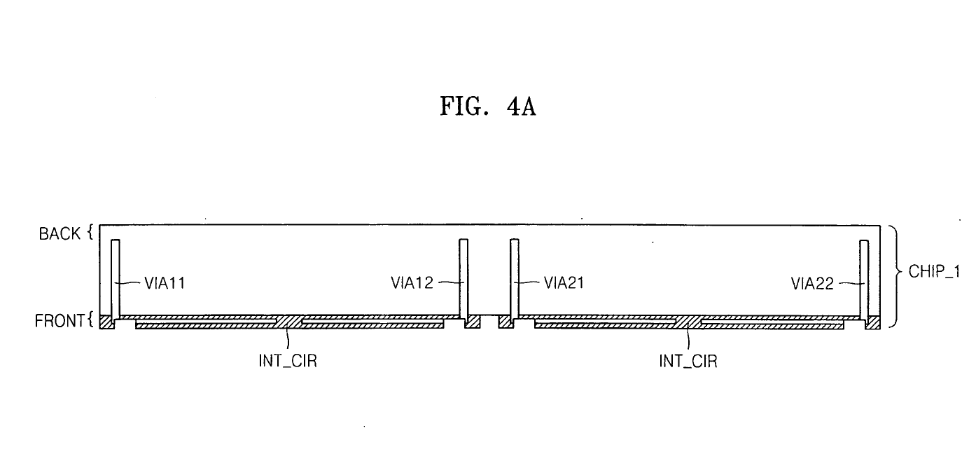

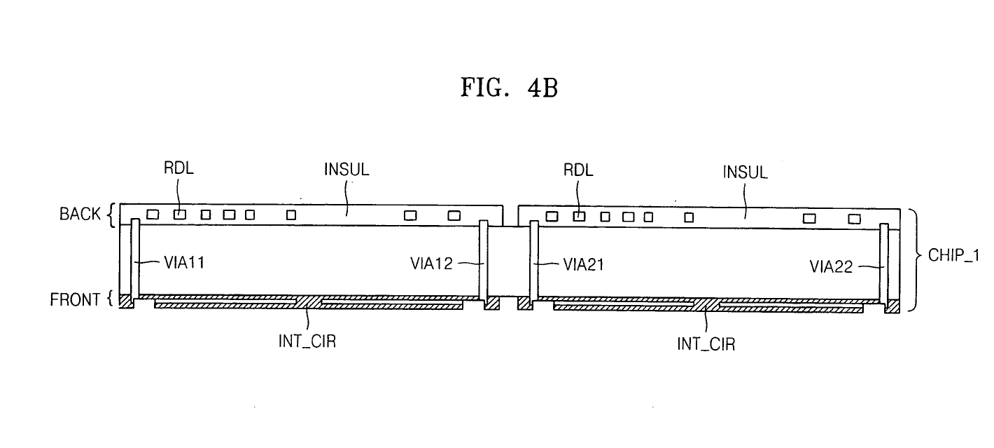

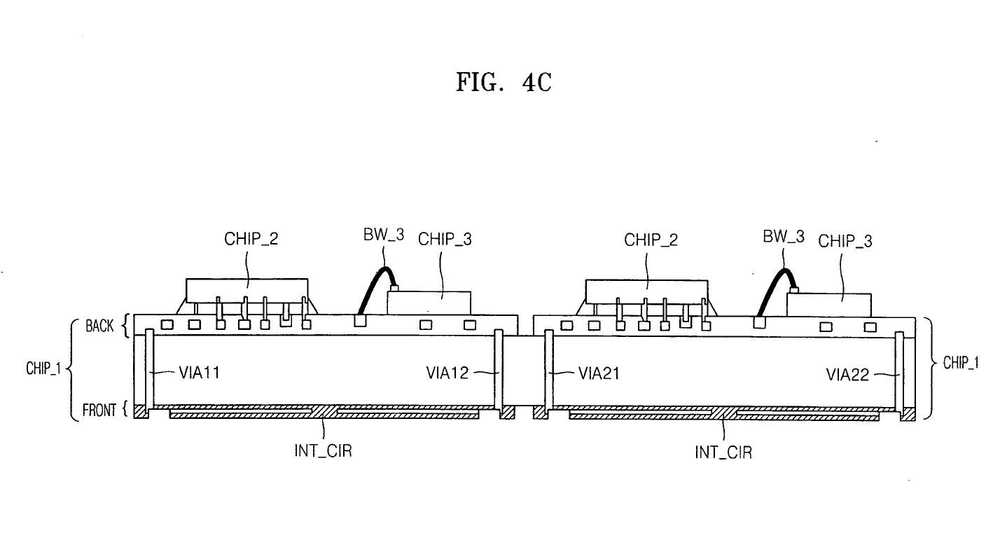

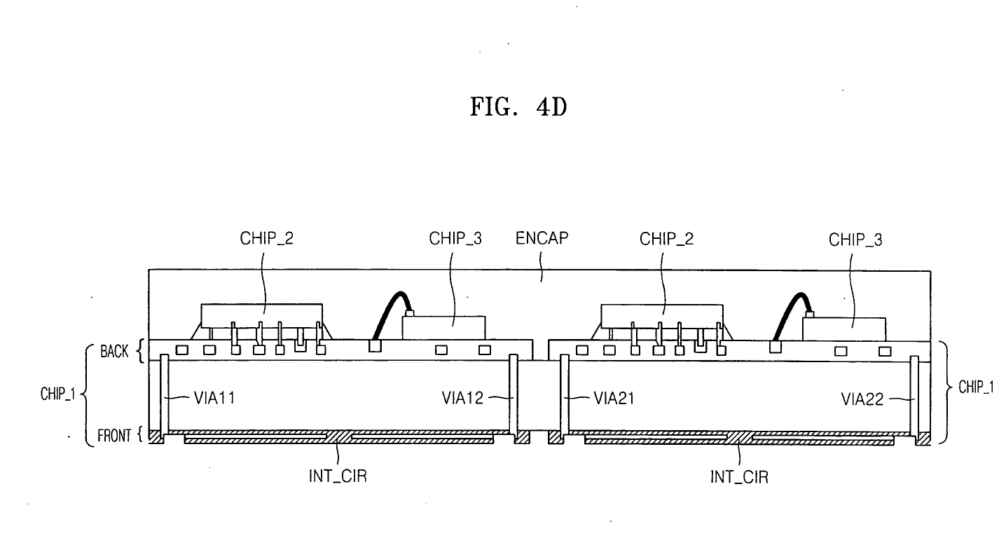

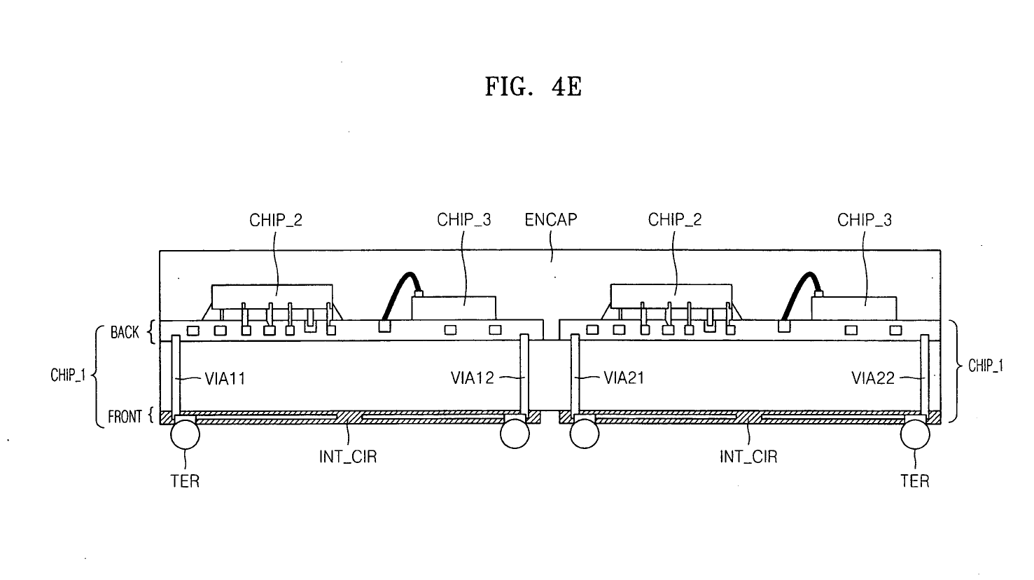

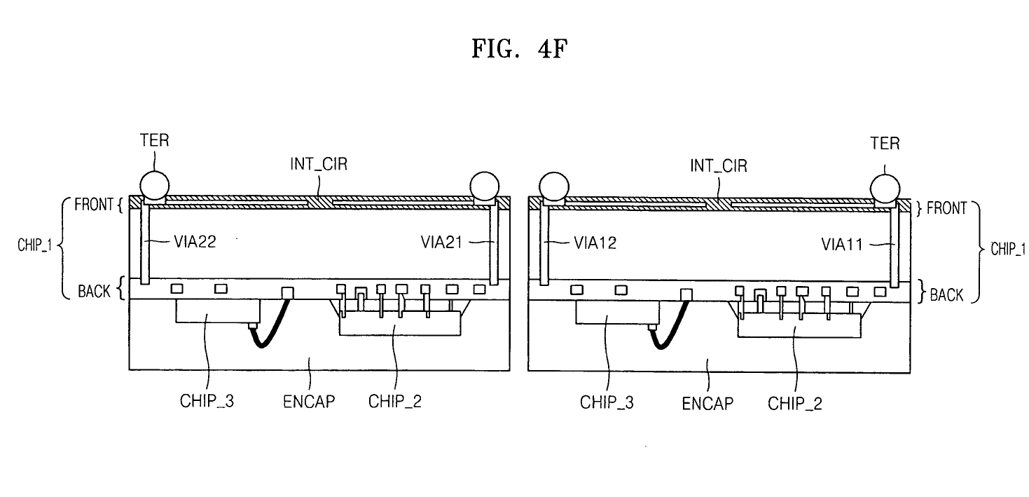

The SiP is manufactured at a wafer level. Hereinafter, an embodiment of a method of manufacturing a SiP, according to aspects of the present invention, will be described in detail with reference to the views of FIGS. 4A through 4F.

Referring to FIG. 4A, four via electrodes VIA11, VIA12, VIA21, and VIA22 for electrically connecting a first surface FRONT of a main chip CHIP_1 with a second surface BACK of the main chip CHIP_1 are formed. In the present invention, the number of via electrodes can vary. In FIG. 4A, the via electrodes VIA11, VIA12, VIA21, and VIA22 are formed to a predetermined depth from the first surface FRONT of the main chip CHIP_1.

An internal circuit INT_CIR is formed on the first surface FRONT of the main chip CHIP_1. In FIG. 4A, the internal circuit INT_CIR is shown as if it has a simple configuration, for illustrative purposes. However, those skilled in the art will appreciate, given the benefit of this disclosure, that the internal circuit INT_CIR would have a more complicated configuration for performing inherent functions of the main chip CHIP_1. Such inherent functions are not essential to the present invention, so not disclosed in detail herein.

Referring to FIG. 4B, the second surface BACK of the main chip CHIP_1 is back-lapped so that the via electrodes VIA11, VIA12, VIA21, and VIA22 are exposed. Then, an RDL is formed on the back-lapped second surface BACK of the main chip CHIP_1. As described above, the RDL is formed in consideration of interconnections between the main chip CHIP_1 and sub chips, as well as the interconnections between the sub chips. The RDL can be formed using a photo-lithography method or an electroplating method, as examples. Then, as illustrated in FIG. 4B, an insulating layer INSUL for insulating the RDL is formed on the second surface BACK of the main chip CHIP_1 on which the RDL is formed.

Referring to FIG. 4C, two sub chips CHIP_2 and CHIP_3 are assembled on the second surface BACK of the main chip CHIP_1. In the present invention, the number of sub chips can vary. The sub chips CHIP_2 and CHIP_3 are electrically connected with the RDL, using a flip chip bonding method, a wire bonding method, or the like. In FIG. 4C, the sub chip CHIP_2 is electrically connected with the RDL by the flip chip bonding method, and the sub chip CHIP_3 is electrically connected with the RDL by a bonding wire BW_3. However, the present invention is not limited to the flip chip bonding method and the wire bonding method. That is, the sub chips CHIP_2 and CHIP_3 can be electrically connected with the RDL, using any of a variety of chip bonding methods.

Referring to FIG. 4D, a protective layer ENCAP is formed to cover the sub chips CHIP_2 and CHIP_3 assembled on the second surface BACK of the main chip CHIP_1. The protective layer ENCAP acts to physically protect the sub chips CHIP_2 and CHIP_3. The protective layer ENCAP can be formed, using a screen printing method, a spin coating method, a laminating method, an injection molding method, or other similar method. However, these protective forming methods are provided as examples, and the protective layer ENCAP can be formed using any of a variety of protective layer forming methods.

As illustrated in FIG. 4D, the RDL, the insulating layer INSUL for insulating the RDL, the sub chips CHIP_2 and CHIP_3 (see also FIG. 4B), and the protective layer ENCAP for covering the sub chips CHIP_2 and CHIP_3 are sequentially stacked on the second surface BACK of the main chip CHIP_1.

Referring to FIG. 4E, external terminals TER are formed on the first surface FRONT of the main chip CHIP_1.

The operation of forming the external terminals TER can be performed before or during the forming of the protective layer ENCAP. The external terminals TER act to electrically connect the SiP with an external device. As described above, a solder ball pad, a bonding pad, a bumping pad, or the like can be used as the external terminals TER.

Referring to FIG. 4F, as illustrated in FIGS. 4A through 4E, when the SiP according to aspects of the present invention is manufactured, a plurality of SiPs having the same structure can be simultaneously formed at a wafer level. FIGS. 4A through 4E illustrate a case where two SiPs having the same structure are simultaneously formed at a wafer level. As such, when a plurality of SiPs having the same structure are simultaneously formed at a wafer level, singulation as illustrated in FIG. 4F is needed. The plurality of SiPs having the same structure, which are simultaneously formed at the wafer level, are divided individually by the singulation. The singulation can be carried out by utilizing a laser or a blade, or other techniques known in the art.

As illustrated in FIG. 4F, the length of the SiP is substantially equal to the length of the main chip CHIP_1. Meanwhile, the length of each sub chip CHIP_2 or CHIP_3 is shorter than the length of the main chip CHIP_1.

As described above, the present invention has an advantage of enhancing chip integration, as follows.

First, the length of a SiP according to aspects of the present invention is substantially equal to the length of a main chip. Accordingly, it is possible to minimize the length of the SiP.

Second, the SiP according to aspects of the present invention does not require a separate substrate, which is different to the case of conventional SiPs. Therefore, according to aspects of the present invention, it is possible to reduce the thickness of a SiP.

While the present invention has been particularly shown and described with reference to exemplary embodiments thereof, it will be understood by those of ordinary skill in the art that various changes in form and details can be made therein without departing from the spirit and scope of the present invention as defined by the following claims. It is intended by the following claims, therefore, to claim that which is literally described and all equivalents thereto, including all modifications and variations that fall within the scope of each claim.

What is claimed is:

1. A system-in-package (SiP) comprising:
a main chip having a first surface electrically connected to a second surface of the main chip through a via electrode;
a ReDistribution Line (RDL) formed on the second surface of the main chip; and
one or more sub chips assembled on the second surface of the main chip, wherein a length of the SiP is substantially equal to a length of the main chip.

2. The SiP of claim 1, wherein the main chip is a chip having the longest length among a plurality of chips included in the SiP.

3. The SiP of claim 1, further comprising an internal circuit of the main chip formed on the first surface of the main chip.

4. The SiP of claim 1, further comprising an external terminal formed on the first surface of the main chip and configured to electrically connect the SiP with an external device.

5. The SiP of claim 4, wherein the external terminal is a solder ball pad, a bonding pad, or a bumping pad.

6. The SiP of claim 1, wherein the main chip includes one or more via electrodes.

7. The SiP of claim 1, wherein the RDL is formed based on the footprints and placement of the one or more sub chips relative to the main chip, and provides efficient interconnections between the main chip and the one or more sub chips and between the one or more sub chips.

8. The SiP of claim 1, further comprising an insulating layer formed on the second surface of the main chip and configured to insulate the RDL.

9. The SiP of claim 1, further comprising a protective layer covering the one or more sub chips assembled on the second surface of the main chip.

10. The SiP of claim 1, further comprising:
an insulating layer formed on the second surface of the main chip and configured to insulate the RDL; and
a protective layer covering the one or more sub chips assembled on the second surface of the main chip,
wherein the RDL, the insulating layer, the one or more sub chips, and the protective layer are sequentially stacked on the second surface of the main chip.

11. The SiP of claim 10, wherein the SiP is formed at a wafer level.

12. A method for manufacturing a system-in-package (SiP),
providing a main chip and one or more sub chips;
forming a via electrode electrically connecting a first surface of the main chip with a second surface of the main chip;
forming a ReDistribution Line (RDL) on the second surface of the main chip; and
assembling the one or more sub chips on the second surface of the main chip on which the RDL is formed, wherein the length of the SiP is substantially equal to the length of the main chip.

13. The method of claim 12, further comprising forming a protective layer covering the one or more sub chips assembled on the second surface of the main chip.

14. The method of claim 12, wherein the length of the main chip is greater than the lengths of the one or more sub chips.

15. The method of claim 12, further comprising forming an internal circuit of the main chip on the first surface of the main chip.

16. The method of claim 12, further comprising forming a plurality of via electrodes through the main chip.

17. The method of claim 12, further comprising forming the RDL based on the footprints and placement of the one or more sub chips, interconnections between the main chip and the one or more sub chips, and interconnections between the one or more sub chips.

18. The method of claim 17, further comprising forming an insulating layer insulating the RDL.

19. The method of claim 12, further comprising electrically connecting the one or more sub chips with the RDL, using a flip chip bonding method or a wire bonding method.

20. The method of claim 12, further comprising forming a protective layer for covering the one or more sub chips using a screen printing method, a spin coating method, a laminating method, or an injection molding method.

21. The method of claim 12, further comprising forming an external terminal electrically connecting the SiP with an external device, on the first surface of the main chip.

22. The method of claim 12, further comprising forming a plurality of SiPs simultaneously to have the same structure at a wafer level.

23. The method of claim 22, further comprising singularizing the plurality of the SiPs.

24. A method for manufacturing a system-in-package (SiP), the method comprising:
providing a main chip and one or more sub chips;
forming an internal circuit on a first surface of the main chip;
forming a via electrode to a predetermined depth in the main chip;
back-lapping a second surface of the main chip so that the via electrode is exposed;
forming a ReDistribution Line (RDL) on the second surface of the back-lapped main chip;
forming an insulating layer insulating the RDL;
assembling the one or more sub chips on the second surface of the main chip so that the one or more sub chips are electrically connected with the RDL;
forming a protective layer covering the one or more sub chips; and
forming an external terminal on the first surface of the main chip.

25. The method of claim 24, wherein the length of the SiP is substantially equal to the length of the main chip.
